(19) United States
(12) Patent Application Publication
(10) Pub. No.: US 2015/0124848 A1
(43) Pub. Date: May 7, 2015

(54) Wavelength Stabilized Diode Laser Module with Limited Back Reflection

(71) Applicants: Alexander Ovtchinnikov, Worcester, MA (US); Alexey Komissarov, Charlton, MA (US); Igor Berishev, Worcester, MA (US); Dmitriy Miftakhutdinov, Worcester, MA (US)

(72) Inventors: Alexander Ovtchinnikov, Worcester, MA (US); Alexey Komissarov, Charlton, MA (US); Igor Berishev, Worcester, MA (US); Dmitriy Miftakhutdinov, Worcester, MA (US)

(73) Assignee: IPG Photonics Corporation, Oxford, MA (US)

(21) Appl. No.: 14/060,682

(22) Filed: Oct. 23, 2013

(51) Int. Cl. H01S 5/026

(52) U.S. Cl. CPC H01S 5/026
USPC 372/50.1

(57) ABSTRACT

A module is configured with a housing enclosing a diode laser. Fast and slow axes collimators are located behind the rear facet of the laser, which along with a front facet, defines an intra-cavity cavity of the laser. The facets are partially transmissive to light and therefore emit laser light. A wavelength selective optical element is aligned with the collimators and configured to reflect light emitted through the back facet and processed by collimators back into the intra-cavity. As a result, the laser beam is emitted through the front facet at a wavelength locked on the desired wavelength of the optical element. A delivery fiber is mechanically coupled to the front facet of diode laser and configured to receive and guide the emitted laser beam along the path of light.

### BACKGROUND OF THE DISCLOSURE

1. Field of the Invention

The invention is related to wavelength stabilized light emitters such as including laser diodes, etc. that have limited backreflection. More specifically, the invention relates to a single frequency diode laser module having a configuration which provides a predetermined stabilized wavelength output while reducing unwanted backreflection into the intra-cavity of the diode laser.

2. Background of the Disclosure

Numerous practical applications require using wavelength stabilized laser diodes, including single mode single frequency semiconductor laser (“SMSFL”) diodes. There are two basic types of SMSF laser diode structures: Fabry-Perot and distributed feedback (DBF). Of the two types of lasers Fabry-Perot diode lasers are the most economical and have excellent performance characteristics.

One of the strictest requirements applied to SMSF diode lasers includes a stabilized output at the desired frequency. Some of the designs of the SMSF diode lasers utilize external-cavity wavelength selecting elements (“WSE”)—optical elements located in the path of light outside the resonant cavity—as feedback elements for providing a single longitudinal mode (frequency) operation.

One WSE for inducing narrowband operation of a single-transverse mode semiconductor laser is a fiber Bragg grating functioning as an extra-cavity element. This device is a narrow-band reflector that functions only in an optical fiber waveguide. Stabilized single-transverse mode laser diodes with a fiber Bragg grating typically have a long external cavity which may be necessary to achieve stable laser output. The length of a cavity is an important factor affecting mode beating: with a greater length of the external cavity the interaction among multiple longitudinal modes increases which may generate unacceptable levels of noise.

Another frequently used WSE includes a volume Bragg grating (VBG), this spectrally selective optical element has been demonstrated as a reliable spectral filter. The SMSF diode laser with an external VBG may generally have two configurations. One configuration incorporates the VBG positioned downstream along a light path from the front facet of the diode laser. The other one features the VBG located upstream from a rear facet and configured to at least partially reflect light generated within the inner cavity between rear and front facets. The latter is of a particular interest here since the disclosed configuration includes a VBG located upstream from the rear facet of a diode laser.

Use of extra-cavity VBG's has been well known in the prior art for many years and the prior art further provides a variety of upstream uses of VBS's. Linke et al. disclose an upstream extra-cavity VBG without any optical delivery system (e.g., without any lenses) in the paper entitled “Wavelength addressable laser diode using a rewritable Bragg grating mirror”. (See CLEO '99, p. 138) The VBG element is positioned in the optical path of the light behind the rear facet of the diode laser without any extra lenses in between. In the case of a waveguide cavity, such as the case for semiconductor laser diodes, only a very small portion of the total laser output power may be returned by the VBG into the laser cavity.

P. Mills et al. disclose alternative optical schematics including as VBG spaced upstream from the rear facet of a diode laser in the paper entitled “SINGLE-MODE OPERATION OF 1.55. μm SEMICONDUCTOR LASER . . . ” (See Electronic Letters 18 Jul. 1985, Vol 21, p. 648-649). The disclosed schematic includes a diode laser, a VBG spaced upstream from the rear facet of the laser, and a focusing system between the VBG and rear facet. The schematic further includes a collimating assembly located at a distance from the front facet of the laser and operative to couple emitted light into a fiber which is fused to the output of the collimating assembly.

All SMSF lasers can be very sensitive to optical feedback or backreflection on the front facet, hence improvements of the above prior art designs are needed. Even if less than a millionth of the output power is sent back to the laser, this may in some cases cause strongly increased phase noise and intensity noise or even chaotic multimode operation. There is always some small amount of optical power in various resonator modes, even though one mode is clearly dominating. The reflected photons reenter the inner cavity interact, albeit to a small degree, with photons at wavelengths different from the peak one. While light generation is unlikely at these non-resonant frequencies, the electron/hole density (carrier concentration) may change. The changed concentration affects the refractive index of a gain medium which leads to changes of the effective cavity length and further to the shift of the resonant frequency. Returning to Mills et al., the disclosed schematic is configured with multiple reflecting surfaces both on the upstream and downstream ends of the schematic.

A need therefore exists for wavelength stabilized diode lasers provided with external-cavity upstream WSE which substantially decreases the amount of light backreflected into the front facet.

### SUMMARY OF THE DISCLOSURE

The disclosed diode laser satisfies this need. In particular, the disclosed emitter is preferably configured as a single transverse mode diode laser with a WSE in the form of a VBG spaced upstream from the rear facet of the diode laser. An optical system including fast and slow axes collimators is positioned between the rear facet of the laser and VBG. The wavelength of the disclosed single transverse mode (“SM”) diode laser is reliably locked to that of the VBG. The opposite, emitting facet of the diode laser is directly coupled to a SM delivery fiber.

One of ordinary skill in the art would grasp that the present invention, although preferably limited to a single transverse mode and a single longitudinal mode output, could provide benefits for a multi-mode transverse output with a single longitudinal mode.

### BRIEF DESCRIPTION OF THE DRAWINGS

The above and other features and advantages of the disclosed diode laser module will become more readily apparent from the following specific description in light of the drawing, in which:

FIG. 1 is a diagrammatic representation of the disclosed module.

FIGS. 2A-2C illustrate respective geometries of a delivery fiber.

### SPECIFIC DESCRIPTION

Reference will now be made in detail to embodiments of the invention. Wherever possible, same or similar numerals are used in the drawings and the description to refer to the same or like parts or steps. The drawings are in simplified form and are not to precise scale. Unless specifically noted, it is intended that the words and phrases in the specification and claims be given the ordinary and accustomed meaning to those of ordinary skill in the fiber laser arts. The word “couple” and similar terms do not necessarily denote direct and immediate connections, but also include mechanical and optical connections through free space or intermediate elements.

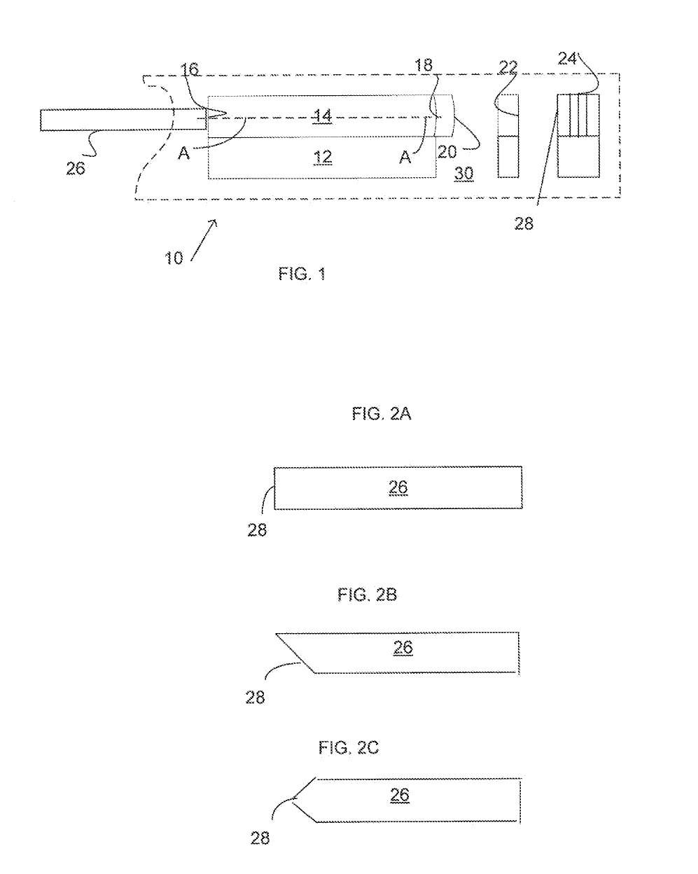

FIG. 1 illustrates the disclosed module 10. The module 10 is configured with a sub-mount 12 supporting a diode laser 14. The rear and front emitting facets 18, 16, respectively, are partially transmissive and define an intra-cavity therebetween. The diode laser 14 is configured to operate in a single transverse mode.

The module 10 further includes a collimator unit configured with a fast axis collimator 20 coupled to rear facet 18 and slow axis collimator 22 which is spaced from collimator 20 and supported by a stand. The light emitted through partially transmissive back facet 18 is fully collimated before it is incident upon a wavelength selective element 24 which is a dispersive element including a surface diffraction grating, transmission amplitude grating, reflection amplitude grating, phase grating, volume Bragg grading (“VBG”) and other suitable discriminators.

Given only as an example, wavelength selective element 24 is a VBG which is recorded in photorefractive material and configured as a partial reflector. Accordingly, VBG 24 and front facet 16 of diode laser 14 define an external cavity therebetween. The entire structure is enclosed within a housing 30.

The front facet 16 of laser 14 is directly coupled to a delivery SM fiber 26. The coupling between laser 14 and fiber 26 may include fusing, gluing and the like depending on the configuration of surfaces to be mechanically connected.

In operation, VBG 24 reflects most of the light in a narrow spectral region. The reflected light is directed back into the laser cavity, thus forming an external cavity and locking the frequency of the laser emission to that of the peak reflectivity of VBG 24. The front facet of the laser 16 should have enough reflectivity for laser 12 to operate above threshold and at a desired output power level. The laser 12 emits radiation through front facet 20 in a single transverse mode and single longitudinal mode which is easy to couple into single mode fiber 26 that guides the coupled light along the path of light.

FIGS. 2A-2C show respective different configuration an end 28 of fiber 26 which is to be coupled to emitting facet 26 of laser 12. FIG. 2A illustrates fiber 26 formed with end 28 which extends perpendicular to the axis A-A of diode laser 14 shown in FIG. 1. FIG. 2 illustrates slanted end 28 of fiber 26 which further minimizes the possibility of backreflection into the inner cavity of diode laser 14. FIG. 2C illustrates a wedge end 28 of fiber 26 configured as a lens which improves coupling of light.

The modulo 10 can be modified to further decrease the backreflection of unwanted light into the inner cavity of laser 4. For example a surface 28 of spectrally selective optical element 24 receiving the light from the inner cavity of laser 14 may be slanted or rounded. Similarly, slow axis collimator 22 may be positioned at an angle differing from a right one with respect to the axis of diode laser 14.

Overall, disclosed module 10 is characterized by a fewer reflecting surfaces, particularly on a downstream end of the disclosed structure, due to the direct coupling between fiber 26 and emitting facet 16 of laser 14. The external cavity between emitting facet 16 and spectrally selective optical element 24 is short which substantially minimizes the mode beating and therefore lowers a level of noise.

It will be apparent to those skilled in the art that various modifications and variations can be made in the presently disclosed SMSFL. Thus, it is intended that the present disclosure cover the modifications and variations of this disclosure provided they come within the scope of the appended claims and their equivalents.

1. A module, comprising:
a diode laser having rear and front facets which define an intra-cavity therebetween, the facets being partially transmissive to light;
a spectrally selective optical element spaced from and opposing the rear facet of the diode laser, the optical element being configured to reflect at least a portion of the light back into the intra-cavity so as to lock a wavelength range of laser beam to a wavelength range of the optical element; and
a fiber directly coupled to the front facet of the diode laser and configured to guide the light at the locked wavelength along a light path.

2. The module of claim 1 further comprising
a fast axis collimator mounted to the rear facet of the diode laser and operative to collimate light, which is coupled from the intra-cavity through the rear facet of the diode laser, along a fast axis;
a slow axis collimator spaced between the fast axis collimator and spectrally selective optical element and configured to collimate the light along a slow axis.

3. The module of claim 1, wherein the fiber is configured to support a single transverse mode.

4. The module of claim 1, wherein an end of the fiber to be directly coupled to the front facet of the diode laser is wedged.

5. The module of claim 1, wherein an end of the fiber to be directly coupled to the front facet of the diode laser extends perpendicular to an axis of the diode laser or at an angle different from a right angle.

6. The module of claim 1 further comprising a sub-mount supporting the diode laser.

7. The module of claim 1, wherein the laser diode produces single transverse mode laser light.

8. The module of claim 1, wherein the wavelength range of the locked wavelength is ±1.0 nm.

9. The module of claim 3 further comprising the housing enclosing the sub-mount, diode laser, fast and slow axes collimators and the spectrally selective optical element.

10. The module of claim 1, wherein the spectrally selective optical element includes a surface diffraction grating, transmission amplitude grating, reflection amplitude grating, phase grating or volume Bragg grading.

11. The module of claim 2, wherein the slow axis collimator extends perpendicular to an axis of the diode laser or at an angle different from the right angle.

12. The module of claim 1, wherein the laser diode emits radiation in multiple transverse modes.
